(19) United States
(12) Patent Application Publication
(10) Pub. No.: US 2026/0052676 A1
(43) Pub. Date: Feb. 19, 2026

(54) SEMICONDUCTOR MEMORY DEVICE

(71) Applicant: Samsung Electronics Co., Ltd., Suwon-si (KR)

(72) Inventor: Kangsub Jeong, Suwon-si (KR)

(21) Appl. No.: 19/025,416

(22) Filed: Jan. 16, 2025

(30) Foreign Application Priority Data
Aug. 16, 2024 (KR) 10-2024-0109813

(51) Int. Cl. H10B 12/00; H01L 21/66; H01L 25/065; H01L 25/18; H10B 80/00

(52) U.S. Cl. CPC H10B 12/482; H01L 22/32; H01L 25/0657; H01L 25/18; H10B 12/315; H10B 80/00

(57) ABSTRACT

A semiconductor memory device includes bitlines, a memory cell array, a plate electrode structure, a bitline shielding structure, and a conductive path. The memory cell array includes memory cells connected to the bitlines. The plurality of memory cells are arranged in the first direction and the second direction. Each memory cell includes a cell transistor and a cell capacitor that are arranged in a third direction perpendicular to the surface of the semiconductor substrate. The plate electrode structure forms a common electrode of cell capacitors included in the plurality of memory cells. The bitline shielding structure is disposed between the plurality of bitlines to block electrical interference between the plurality of bitlines. The capacitance-connection conductive path electrically connects the plate electrode structure and the bitline shielding structure.

### CROSS-REFERENCE TO RELATED APPLICATION

This U.S. non-provisional application claims priority under 35 USC § 119 to Korean Patent Application No. 10-2024-0109813, filed on Aug. 16, 2024, in the Korean Intellectual Property Office (KIPO), the disclosure of which is incorporated by reference herein in its entirety.

### BACKGROUND

Recently, the electronics market has seen a rapid increase in the demand for portable devices, which has led to miniaturization and lightweighting of electronic components, such as semiconductor memory devices mounted in the portable devices. To realize miniaturization and lighter weights of the semiconductor memory devices, the individual size of the mounting components is reduced, but electrical characteristics can be degraded in the process.

### SUMMARY

In a first general aspect, a semiconductor memory device includes: a plurality of bitlines, a memory cell array, a plate electrode structure, a bitline shielding structure, and a capacitance-connection conductive path. The plurality of bitlines are arranged in a first direction parallel to a surface of a semiconductor substrate and extending in a second direction parallel to the surface of the semiconductor substrate and perpendicular to the first direction. The memory cell array includes a plurality of memory cells connected to the plurality of bitlines. The plurality of memory cells are arranged in the first direction and the second direction. Each memory cell includes a cell transistor and a cell capacitor that are arranged in a third direction perpendicular to the surface of the semiconductor substrate. The plate electrode structure forms a common electrode of cell capacitors included in the plurality of memory cells. The bitline shielding structure is disposed between the plurality of bitlines to block electrical interference between the plurality of bitlines. The capacitance-connection conductive path connects the plate electrode structure and the bitline shielding structure.

In a second general aspect, a semiconductor memory device includes: a plurality of bitlines, a memory cell array including a plurality of memory cells connected to the plurality of bitlines, each memory cell including a cell transistor and a cell capacitor, a plate electrode structure configured to provide a plate voltage commonly to the plurality of memory cells, a bitline shielding structure disposed between the plurality of bitlines to block electrical interference between the plurality of bitlines, and a capacitance-connection conductive path connecting the plate electrode structure and the bitline shielding structure.

In a third general aspect, a semiconductor memory device includes: a plurality of bitlines arranged in a first direction parallel to a surface of a semiconductor substrate and extending in a second direction parallel to the surface of the semiconductor substrate and perpendicular to the first direction, a memory cell array including a plurality of memory cells connected to the plurality of bitlines, the plurality of memory cells being arranged in the first direction and the second direction, each memory cell including a vertical channel transistor in which a channel extends in the third direction and a cell capacitor that is disposed above the vertical channel transistor in the third direction, a plate electrode structure forming a common electrode of cell capacitors included in the plurality of memory cells, a bitline shielding structure disposed between the plurality of bitlines to block electrical interference between the plurality of bitlines, and a capacitance-connection conductive path connecting the plate electrode structure and the bitline shielding structure. The semiconductor memory device is divided into a memory core region in which the memory cell array is formed, and a peripheral circuit region disposed adjacent to the memory core region in the first direction or the second direction. The capacitance-connection conductive path includes a peripheral connection conductive path formed in the peripheral circuit region and a core connection conductive path formed in the core circuit region.

In some implementations, a semiconductor memory device and an electronic device including the same can have enhanced electrical characteristics compared to conventional semiconductor memory and electronic devices. For example, the semiconductor memory device can increase the capacitance of a plate electrode structure and stabilize the voltage of capacitor electrodes by connecting the plate electrode structure and a bitline shielding structure using the capacitance-connection conductive path, thereby improving the electrical performance of the semiconductor memory device.

Furthermore, the semiconductor memory device can reduce electrical interference between bitlines by connecting the plate electrode structure and the bitline shielding structure using the capacitance-connection conductive path, thereby further improving the electrical performance of the semiconductor memory device.

### BRIEF DESCRIPTION OF THE DRAWINGS

FIG. 1 is a diagram illustrating an example of a semiconductor memory device.

FIGS. 2, 3, 4A and 4B are diagrams illustrating examples of a capacitance-connection conductive path included in a semiconductor memory device.

FIG. 5 is a block diagram illustrating an example of a semiconductor memory device.

FIG. 6 is a diagram illustrating an example of a bank array included in a semiconductor memory device.

FIGS. 7, 8, 9, and 10 are diagrams illustrating an example of a semiconductor memory device including a vertical channel transistor.

FIGS. 11 and 12 are diagrams illustrating an example of a bitline shielding structure included in a semiconductor memory device.

FIGS. 13 and 14 are diagrams illustrating another example of a bitline shielding structure included in a semiconductor memory device.

FIG. 15 is a perspective view of an example of a memory core circuit included in a semiconductor memory device.

FIG. 16 is a diagram illustrating an example layout of a sub peripheral circuit included in the memory core circuit of FIG. 15.

FIG. 17 is a diagram illustrating an example of an arrangement of bitlines included in the memory core circuit of FIG. 15.

FIG. 18 is a diagram illustrating examples of a capacitance-connection conductive path included in a semiconductor memory device.

FIG. 19 is a diagram illustrating an example of a stacked memory device.

FIG. 20 is a diagram illustrating an example structure of a semiconductor package including a semiconductor memory device.

FIG. 21 is a block diagram illustrating an example of a mobile system including a semiconductor memory device.

In the drawings, like numerals refer to like elements throughout. The repeated descriptions may be omitted.

### DETAILED DESCRIPTION

Hereinafter, two directions parallel to the top surface of the semiconductor substrate and intersecting each other are defined as a first direction D1 and a second direction D2, respectively, and a direction substantially perpendicular to the top surface of the semiconductor substrate is defined as a third direction D3. For example, the first direction D1 and the second direction D2 may intersect substantially perpendicular to each other. The first direction D1 may be referred to as a row direction or a first horizontal direction, the second direction D2 may be referred to as a column direction or a second horizontal direction, and the third direction D3 may be referred to as a vertical direction. In the drawings, the direction indicated by an arrow and its opposite direction are described as the same direction. The definitions of the aforementioned directions are the same in all subsequent drawings.

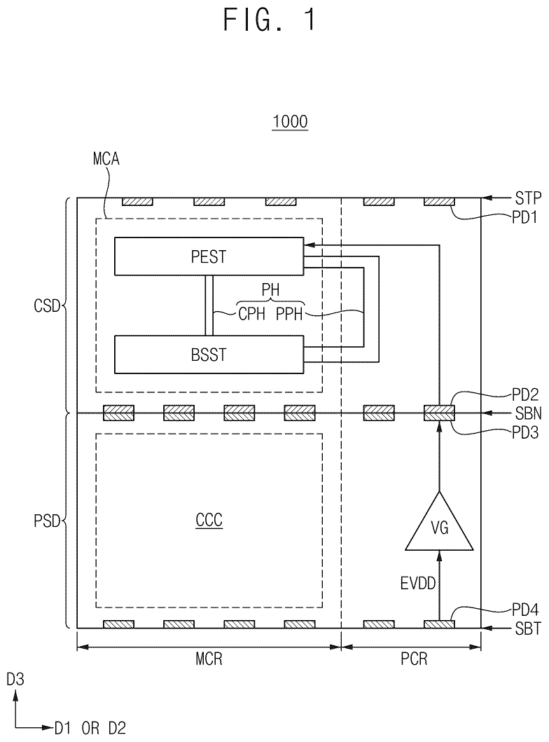

FIG. 1 is a diagram illustrating an example of a semiconductor memory device.

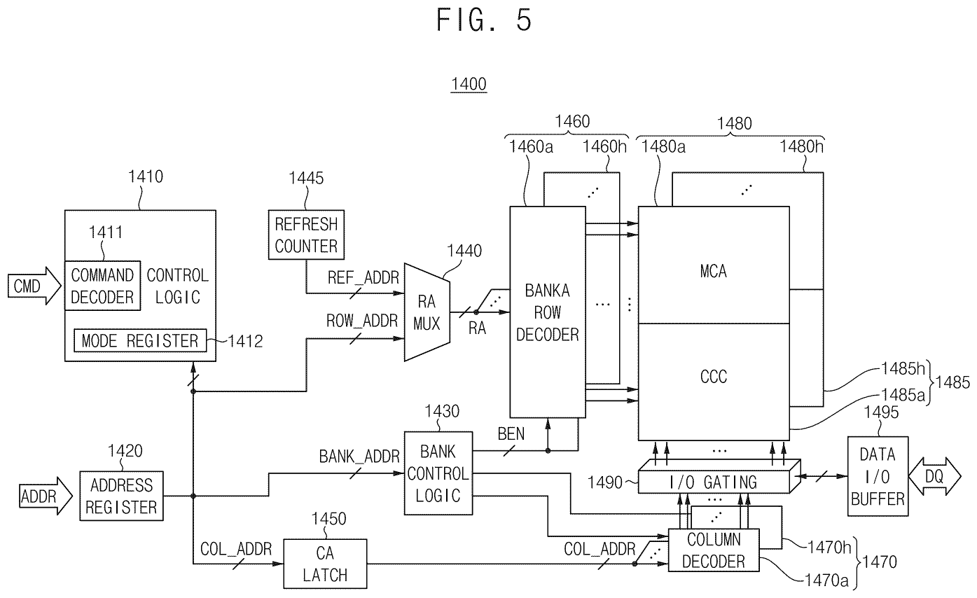

Referring to FIG. 1, a semiconductor memory device 1000 includes a plurality of bitlines, a memory cell array MCA, a plate electrode structure PEST, a bitline shielding structure BSST, and a capacitance-connection conductive path PH. Components for illustrating examples are shown in FIG. 1, and components such as bitlines are omitted for convenience of illustration. A more detailed configuration of the semiconductor memory device will be described below with reference to FIGS. 5 through 10.

As will be described below, the plurality of bitlines may be arranged in a first direction D1 parallel to a surface of a semiconductor substrate and extend in a second direction D2 parallel to the surface of the semiconductor substrate and perpendicular to the first direction D1.

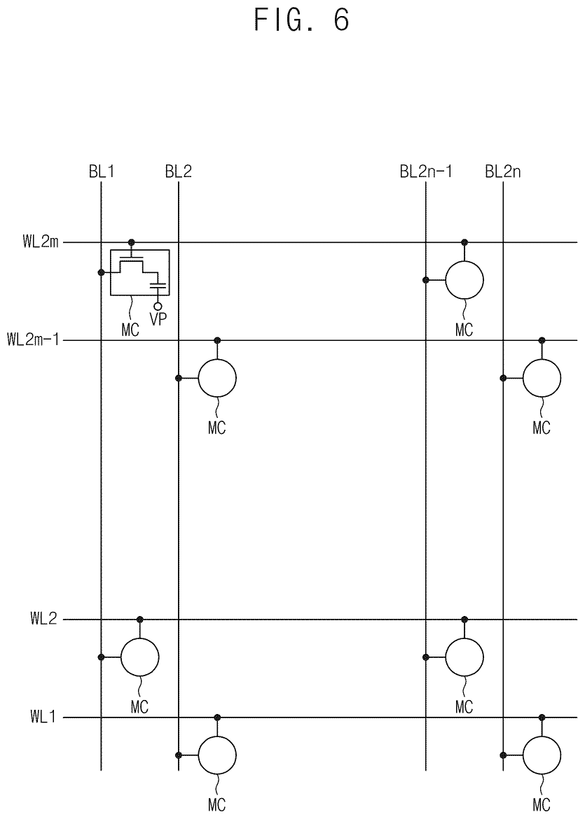

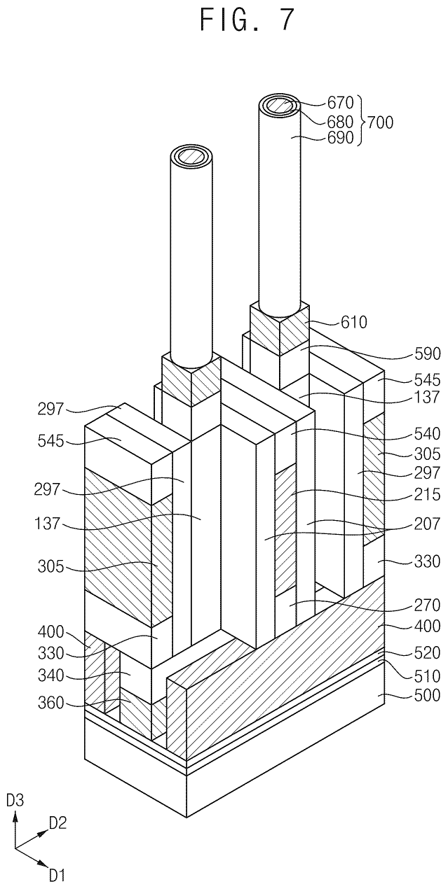

As will be described below, the memory cell array MCA may include a plurality of memory cells. The memory cells may be connected to the plurality of bitlines and arranged in the first direction D1 and the second direction D2. In this disclosure, the phrase “connect” is understood to mean “electrically connect,” unless otherwise indicated. As will be described further with reference to FIG. 6, each memory cell may be a dynamic random memory (DRAM) cell including a cell transistor and a cell capacitor. In an example, as will be described below with reference to FIGS. 7 through 10, the cell transistor may be a vertical channel transistor (VCT) having a channel extending in a third direction D3, and the cell capacitor may be disposed above the vertical channel transistor in the third direction D3.

The plate electrode structure PEST may form a common electrode of the cell capacitors included in the plurality of memory cells. The plate electrode structure PEST may correspond to the second capacitor electrodes described with reference to FIGS. 7 through 10, or may be connected in common to the second capacitor electrodes.

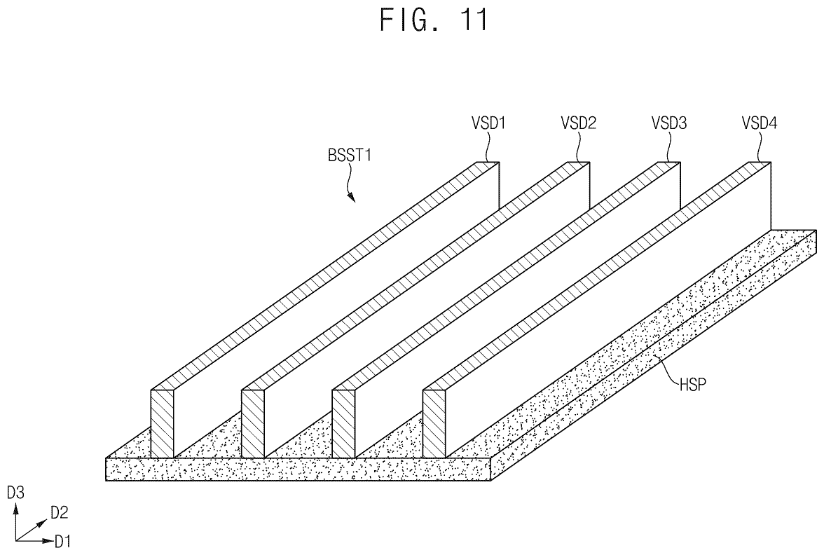

The bitline shielding structure BSST may be disposed between the plurality of bitlines to block electrical interference. Examples of the bitline shielding structure BSST will be further described below with reference to FIGS. 11 through 14.

The capacitance-connection conductive path PH may connect the plate electrode structure PEST and the bitline shielding structure BSST. The capacitance-connection conductive path PH may include conductors such as pads, vertical contacts, and the like. In other words, the plate electrode structure PEST and the bitline shielding structure BSST may be electrically via the capacitance-connection conductive path PH.

As the number of memory cells included in the semiconductor memory device increases, the fluctuation of the charges stored in the cell capacitors increases during a sensing operation, which increases the voltage fluctuation across the plate electrode structure PEST to which a plate voltage VP is applied. This voltage fluctuation affects the voltages developed on the bitlines during the sensing operation and may increase the sensing error. Compared to the conventional structure, in the VCT structure described below with reference to FIGS. 7 through 10, the capacitors are formed above the memory cells and the bitlines are formed below the memory cells, such that the capacitance facing the plate electrode structure PEST and the bitlines is eliminated. As a result, the capacitance of the plate electrode structure PEST becomes smaller, which deteriorates the electrical characteristics of the memory cells. Furthermore, as the density of the semiconductor memory device increases, the spacing between the bitlines becomes smaller, which increases the electrical interference between the bitlines and deteriorates the electrical characteristics of the semiconductor memory device.

In the semiconductor memory device 1000, by connecting the plate electrode structure PEST and the bitline shielding structure BSST using the capacitance-connection conductive path PH, the capacitance of the plate electrode structure PEST may be efficiently increased and the voltage of the capacitor electrodes may be stabilized, thereby improving the electrical performance of the semiconductor memory device 1000. Thus, the conductive path is referred to as a “capacitance-connection conductive path.”

Furthermore, the semiconductor memory device 1000 may efficiently reduce electrical interference between bitlines by connecting the plate electrode structure PEST and the bitline shielding structure BSST using the capacitance-connection conductive path PH, thereby further improving the electrical performance of the semiconductor memory device 1000.

In an example, as shown in FIG. 1, the semiconductor memory device 1000 may have a cell over periphery (CoP) structure in which a core semiconductor die CSD and a peripheral semiconductor die PSD are stacked in a third direction D3 by a bonding method. Pads PD2 formed on the bottom surface of the core semiconductor die CSD and pads PD3 formed on the top surface of the peripheral semiconductor die PSD are bonded to each other such that the core semiconductor die CSD and the peripheral semiconductor die PSD may be connected to each other. The bottom surface of the core semiconductor die CSD and the top surface of the peripheral semiconductor die PSD correspond to a bonding surface SBN.

Test pads PD1 may be formed on the top surface of the core semiconductor die CSD. The test pads PD1 may be used during the testing process of the semiconductor memory device 1000 and may be disabled after the semiconductor memory device 1000 is shipped.

I/O pads PD4 may be formed on the bottom surface of the peripheral semiconductor die PSD. The I/O pads PD4 may be used for communication with external devices, such as a memory controller.

Further, the semiconductor memory device 1000 may be divided into a memory core region MCR and a peripheral circuit region PCR adjacent to the memory core region MCR in the first direction D1 or the second direction D2.

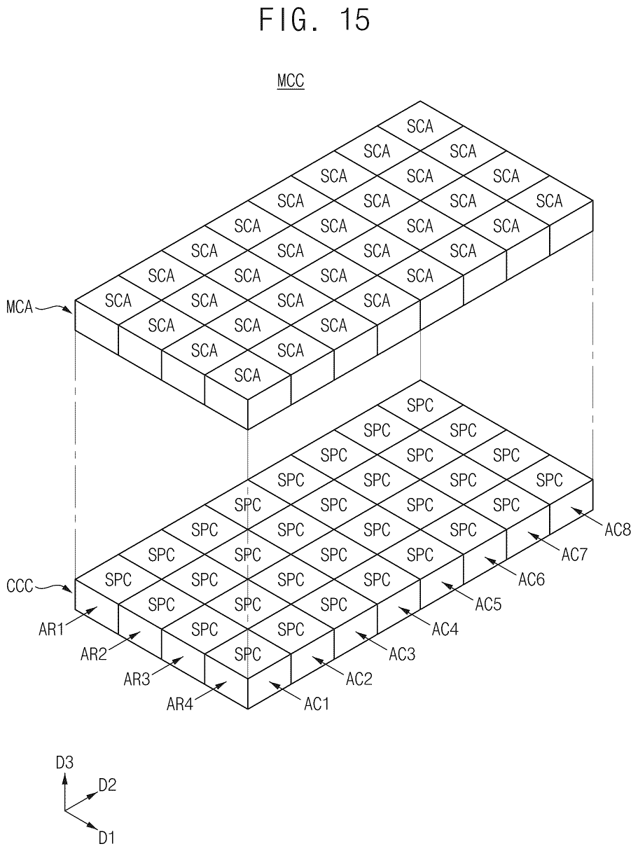

In the memory core region MCR of the core semiconductor die CSD, the memory cell array MCA, the plate electrode structure PEST, and the bitline shielding structure BSST may be formed, and in the memory core region MCR of the peripheral semiconductor die PSD, a core control circuit CCC may be formed. The plate electrode structure PEST and the bitline shielding structure BSST may be considered to be included in the memory cell array MCA. The memory cell array MCA and the core control circuit CCC may be referred to as a memory core circuit. The memory core circuit will be described further with reference to FIGS. 15 through 18.

In the peripheral circuit region PCR of the peripheral semiconductor die PSD, device peripheral circuits such as a voltage generator VG may be formed. The voltage generator VG may generate the plate voltage VP that is applied to the plate electrode structure PEST, based on an external voltage EVDD received via the input-output pad PD4.

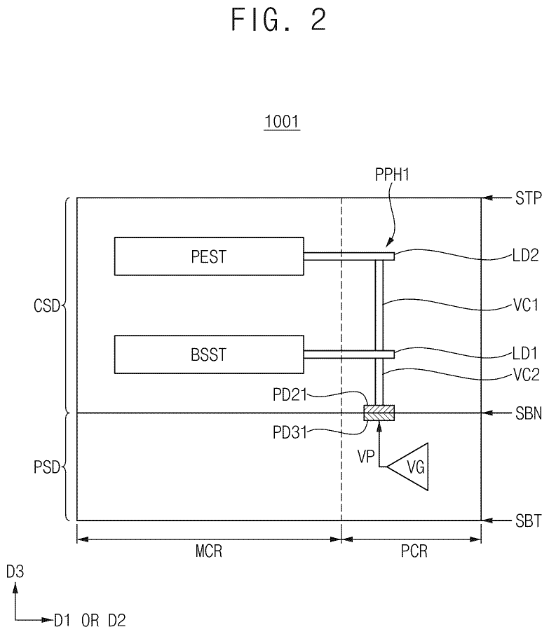

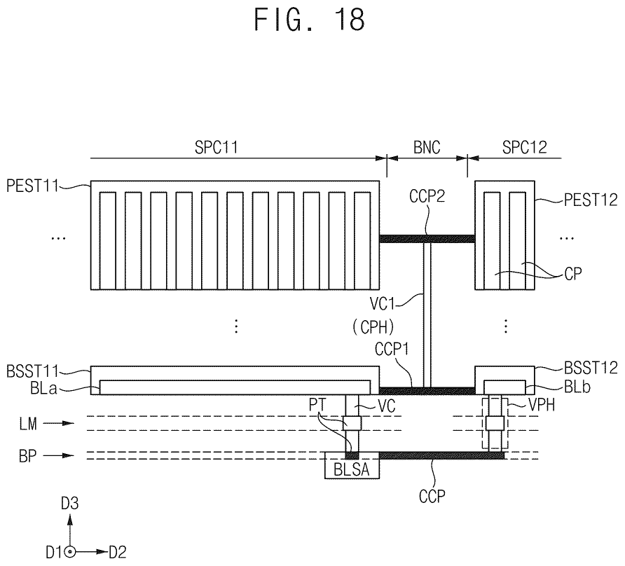

In some examples, the capacitance-connection conductive path PH may include a peripheral connected conductive path PPH formed in the peripheral circuit region PCR. Examples of the peripheral connecting conductive path PPH will be described below with reference to FIGS. 2 through 4B. In some examples, the capacitance-connection conductive path PH may include a core connection conductive path CPH formed in the memory core region MCR. Examples of the core connection conductive path CPH will be described below with reference to FIG. 18. In some examples, the capacitance-connection conductive path PH may include both the peripheral connection conductive path PPH and the core connection conductive path CPH.

FIGS. 2, 3, 4A and 4B are diagrams illustrating examples of a capacitance-connection conductive path included in a semiconductor memory device. Since the semiconductor memory devices 1001, 1002, 1003, 1004 of FIGS. 2, 3, 4A and 4B are similar to the semiconductor memory device 1000 of FIG. 1, the capacitance-connection conductive path PH will be described below, omitting redundant descriptions.

Referring to FIG. 2, a peripheral connection conductive path PPH1 of a semiconductor memory device 1001 may include a first voltage-applied conductive line LD1, a second voltage-applied conductive line LD2, and a vertical contact VC1. In this specification, a voltage-applied conductive line is a conductive line electrically coupled to a voltage source, e.g., voltage generator VG.

The first voltage-applied conductive line LD1 may be connected to the bitline shielding structure BSST and may extend in a first direction D1 or a second direction D2. The second voltage-applied conductive line LD2 may be connected to the plate electrode structure PEST and may extend in the first direction D1 or the second direction D2.

The vertical contact VC1 may extend in the third direction D3 to connect the first voltage-applied conductive line LD1 and the second voltage-applied conductive line LD2. The plate electrode structure PEST and the bitline shielding structure BSST may be connected via the peripheral connection conductive path PPH.

The plate voltage VP generated by the voltage generator VG may be applied to the peripheral connection conductive path PPH via the peripheral pad PD31, the core pad PD21, and the vertical contact VC2, resulting in the common plate voltage VP being applied to the plate electrode structure PEST and the bitline shielding structure BSST.

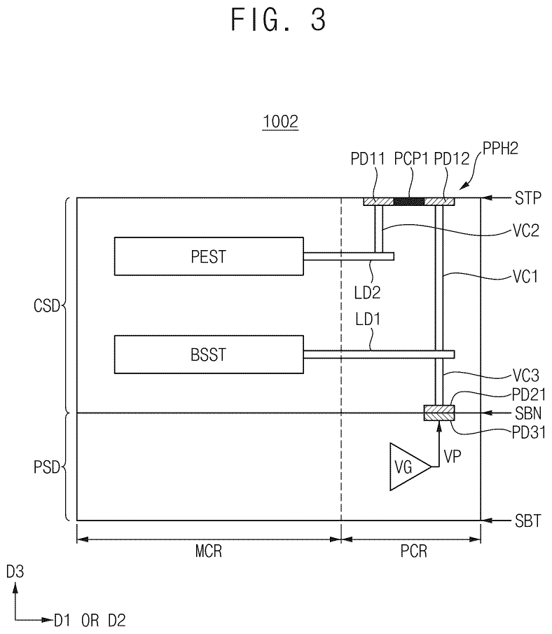

Referring to FIG. 3, a peripheral connection conductive path PPH2 of a semiconductor memory device 1002 may include a first voltage-applied conductive line LD1, a second voltage-applied conductive line LD2, a first test pad PD11, a second test pad PD12, a first vertical contact VC1, a second vertical contact VC2, and a pad-connection conductive line PCP1.

The first voltage-applied conductive line LD1 may be connected to the bitline shielding structure BSST and may extend in the first direction D1 or the second direction D2. The second voltage-applied conductive line LD2 may be connected to the plate electrode structure PEST and may extend in the first direction D1 or the second direction D2. The first test PD11 and the second test pad PD12 may be formed on the top surface STP of the core semiconductor die CSD.

The first vertical contact VC1 may extend in the third direction D3 to connect the first voltage-applied conductive line LD1 and the first test pad PD11. The second vertical contact VC2 may extend in the third direction D3 to connect the second voltage-applied conductive line LD2 and the second test pad PD12. The pad-connection conductive line PCP1 may be formed on the top surface of the core semiconductor die CSD and may connect the first test pad PD11 and the second pad PD12.

The plate voltage VP generated by the voltage generator VG may be applied to the peripheral connection conductive path PPH via the peripheral pad PD31, the core pad PD21, and the vertical contact VC3. As a result, the plate voltage VP may be applied in common to the plate electrode structure PEST and the bitline shielding structure BSST.

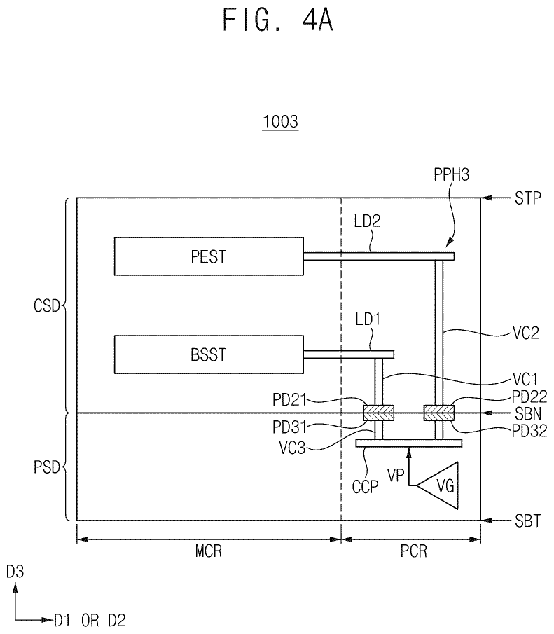

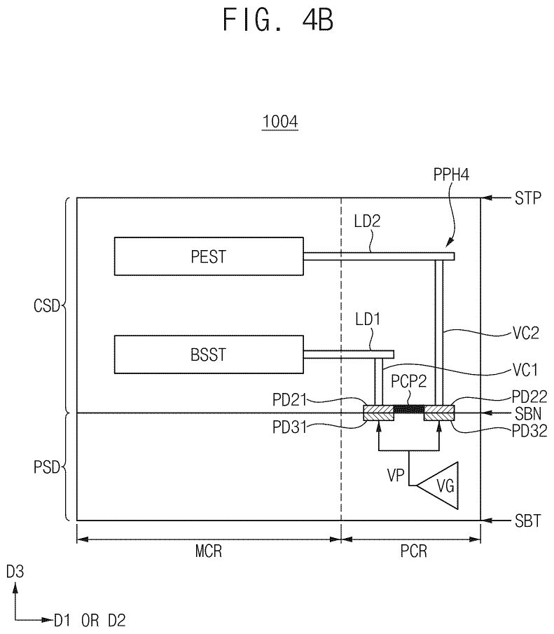

Referring to FIG. 4A, a peripheral connection conductive path PPH3 of a semiconductor memory device 1003 may include a first voltage-applied conductive line LD1, a second voltage-applied conductive line LD2, a first core pad PD21, a second core pad PD22, a first vertical contact VC1, a second vertical contact VC2, a first peripheral pad PD31, a second peripheral pad PD32, a horizontal conductive line CCP, a third vertical contact VC3, and a fourth vertical contact VC4.

The first voltage-applied conductive line LD1 may be connected to the bitline shielding structure BSST and may extend in the first direction D1 or the second direction D2. The second voltage-applied conductive line LD2 may be connected to the plate electrode structure PEST and may extend in the first direction D1 or the second direction D2. The first core pad PD21 and the second core pad PD22 may be formed on the bottom surface of the core semiconductor die CSD, i.e., on the bonding surface SBN.

The first vertical contact VC1 may extend in the third direction D3 to connect the first voltage-applied conductive line LD1 and the first core pad PD21. The second vertical contact VC2 may extend in the third direction D3 to connect the second voltage-applied conductive line LD2 and the second core pad PD22.

The first peripheral pad PD31 and the second peripheral pad PD32 may be formed on the top surface, i.e., the bonding surface SBN, of the peripheral semiconductor die PSD bonded to the lower surface of the core semiconductor die CSD and may be bonded with the first core pad PD21 and the second core pad PD22. The horizontal conductive line CCP may be formed on the peripheral semiconductor die PSD and may extend in the first direction D1 or the second direction D2.

The third vertical contact VC3 may extend in the third direction D3 to connect the first peripheral pad PD31 and the horizontal conductive line CCP. The fourth vertical contact VC4 may extend in the third direction D3 to connect the second peripheral pad PD31 and the horizontal conductive line CCP.

The plate voltage VP generated by the voltage generator VG may be applied to the horizontal conductive line CCP, which is formed on the peripheral semiconductor die PSD and forms a portion of the peripheral connecting conductive path PPH. As a result, the common plate voltage VP may be applied to the plate electrode structure PEST and the bitline shielding structure BSST.

Referring to FIG. 4B, a peripheral connection conductive path PPH4 of a semiconductor memory device 1004 may include a first voltage-applied conductive line LD1, a second voltage-applied conductive line LD2, a first core pad PD21, a second core pad PD22, a first vertical contact VC1, a second vertical contact VC2, and a pad-connection conductive line PCP2.

The first voltage-applied conductive line LD1 may be connected to the bitline shielding structure BSST and may extend in the first direction D1 or the second direction D2. The second voltage-applied conductive line LD2 may be connected to the plate electrode structure PEST and may extend in the first direction D1 or the second direction D2. The first core pad PD21 and the second core pad PD22 may be formed on the bottom surface of the core semiconductor die CSD, e.g., on the bonding surface SBN.

The first vertical contact VC1 may extend in the third direction D3 to connect the first voltage-applied conductive line LD1 and the first core pad PD21. The second vertical contact VC2 may extend in the third direction D3 to connect the second voltage-applied conductive line LD2 and the second core pad PD22.

The pad-connection conductive line PCP3 may be formed on the bottom surface of the core semiconductor die CSD and may connect the first core pad PD21 and the second core pad PD22. In an example, the first core pad PD21, the second core pad PD22, and the pad-connection conductive line PCP2 may be integrally formed as a single pad.

The plate voltage VP generated by the voltage generator VG may be applied to the peripheral connecting conductive path PPH through the peripheral pads PD31, PD32 formed on the peripheral semiconductor die PSD. As a result, the common plate voltage VP may be applied to the plate electrode structure PEST and the bitline shielding structure BSST.

FIG. 5 is block diagram illustrating an example of a semiconductor memory device.

Referring to FIG. 5, a memory device 1400 includes a control logic 1410, an address register 1420, a bank control logic 1430, a row address multiplexer 1440, a column address latch 1450, a row decoder 1460, a column decoder 1470, a memory cell array MCA 1480, a core control circuit CCC 1485, an input-output (I/O) gating circuit 1490, a data input-output (I/O) buffer 1495, and a refresh counter 1445. The components other than the memory cell array 1480 and the core control circuit 1485 may be referred to as “device peripheral circuits”.

The memory cell array 1480 may include a plurality of bank arrays 1480a-480h. The row decoder 1460 may include a plurality of bank row decoders 1460a-460h respectively coupled to the bank arrays 1480a-480h. The column decoder 1470 may include a plurality of bank column decoders 1470a-470h respectively coupled to the bank arrays 1480a-480h, and the core control circuit 1485 may include a plurality of bank core control circuits 1485a-485h respectively coupled to the bank arrays 1480a-480h. The plurality of bank arrays 1480a-480h and the plurality of bank core control circuits 1485a-485h may be stacked in a vertical direction to form a CoP structure.

The address register 1420 may receive an address ADDR including a bank address BANK_ADDR, a row address ROW_ADDR and a column address COL_ADDR from a memory controller. The address register 1420 may provide the received bank address BANK_ADDR to the bank control logic 1430 and may provide the received row address ROW_ADDR to the row address multiplexer 1440. In addition, the address register 1420 may provide the received column address COL_ADDR to the column address latch 1450.

The bank control logic 1430 may generate bank control signals in response to the bank address BANK_ADDR. The bank control signals may include bank enable signals BEN to activate a selection memory bank corresponding to the bank address BANK_ADDR. One of the bank row decoders 1460a-460h corresponding to the bank address BANK_ADDR may be activated in response to the bank control signals, and one of the bank column decoders 1470a-470h corresponding to the bank address BANK_ADDR may be activated in response to the bank control signals.

The row address multiplexer 1440 may receive the row address ROW_ADDR from the address register 1420 and may receive a refresh row address REF_ADDR from the refresh counter 1445. The row address multiplexer 1440 may selectively output the row address ROW_ADDR or the refresh row address REF_ADDR as a row address RA. The row address RA that is output from the row address multiplexer 1440 may be applied to the bank row decoders 1460a-460h.

The activated one of the bank row decoders 1460a-460h may decode the row address RA that is output from the row address multiplexer 1440 and may activate a word-line corresponding to the row address RA. For example, the activated bank row decoder may apply a word-line driving voltage to the word-line corresponding to the row address RA.

The column address latch 1450 may receive the column address COL_ADDR from the address register 1420 and may temporarily store the received column address COL_ADDR. In some examples, in a burst mode, the column address latch 1450 may generate column addresses that increment from the received column address COL_ADDR. The column address latch 1450 may apply the temporarily stored or generated column address to the bank column decoders 1470a-470h.

The activated one of the bank column decoders 1470a-470h may decode the column address COL_ADDR that is output from the column address latch 1450 and may control the input-output I/O gating circuit 1490 to output data corresponding to the column address COL_ADDR.

The I/O gating circuit 1490 may include a circuitry for gating input-output data. The I/O gating circuit 1490 may further include read data latches and write drivers. The read data latches are for storing data that is output from the bank arrays 1480a-480h, and the write drivers are for writing data to the bank arrays 1480a-480h.

Data to be read from one bank array of the bank arrays 1480a-480h may be sensed by the CCC 1485 coupled to the one bank array from which the data is to be read and may be stored in the read data latches. The data stored in the read data latches may be provided to the memory controller via the data I/O buffer 1495. Data DQ to be written in one bank array of the bank arrays 1480a-480h may be provided to the data I/O buffer 1495 from the memory controller. The write driver may write the data DQ in one bank array of the bank arrays 1480a-480h.

The control logic 1410 may control operations of the memory device 1400. For example, the control logic 1410 may generate control signals for the memory device 1400 to perform a write operation or a read operation. The control logic 1410 may include a command decoder 1411 and a mode register set 1412. The command decoder decodes a command CMD received from the memory controller, and the mode register set 1412 sets an operation mode of the memory device 1400.

For example, the command decoder 1411 may generate the control signals corresponding to the command CMD by decoding a write enable signal, a row address strobe signal, a column address strobe signal, a chip selection signal, etc.

FIG. 6 is a diagram illustrating an example of a bank array included in a semiconductor memory device.

Referring to FIG. 6, a bank array includes a plurality of wordlines WL1 to WL2m, where m is a binary integer, a plurality of bitlines BL1 to BL2n, where n is a binary integer, and a plurality of memory cells MC disposed at intersections between the wordlines WL1 to WL2m and the bitlines BL1 to BL2n. As shown in FIG. 6, each memory cell MC may have a DRAM cell structure. The memory cells MC may include a cell capacitor connected to a plate voltage VP and a cell transistor connected between each bitline and the cell capacitor and the gate electrode of the cell transistor is connected to each wordline. The wordlines to which the memory cells MC are connected may be defined as rows of the bank array, and the bitlines to which the memory cells MC are connected may be defined as columns of the bank array.

The semiconductor memory device may be a DRAM device as described with reference to FIGS. 5 and 6, but examples are not limited to any particular type of memory.

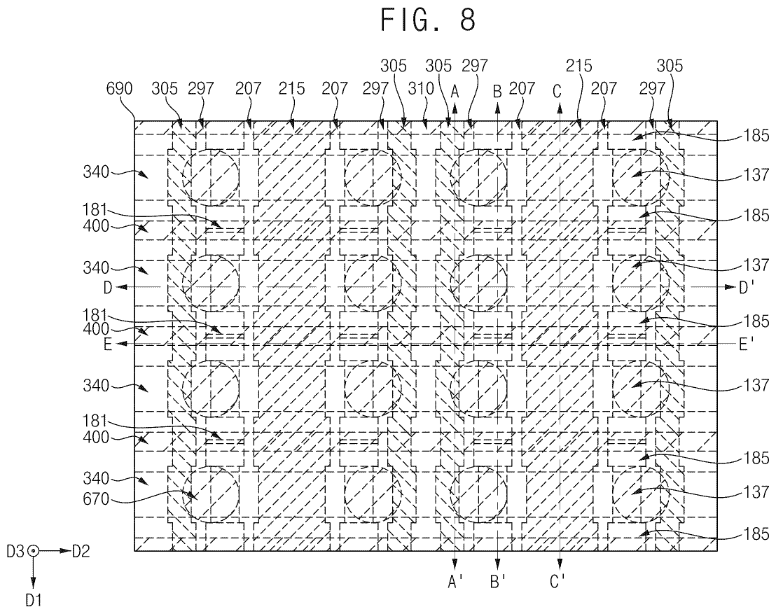

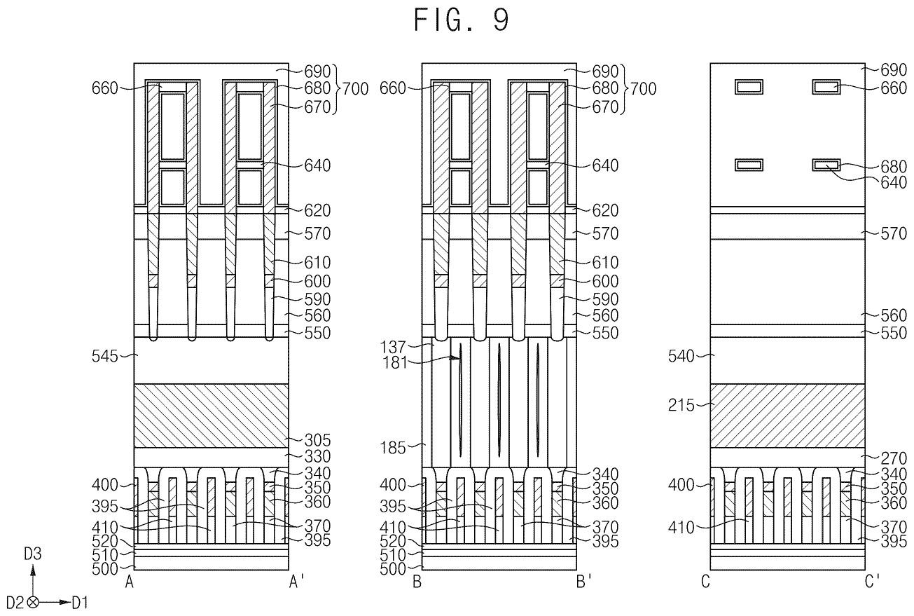

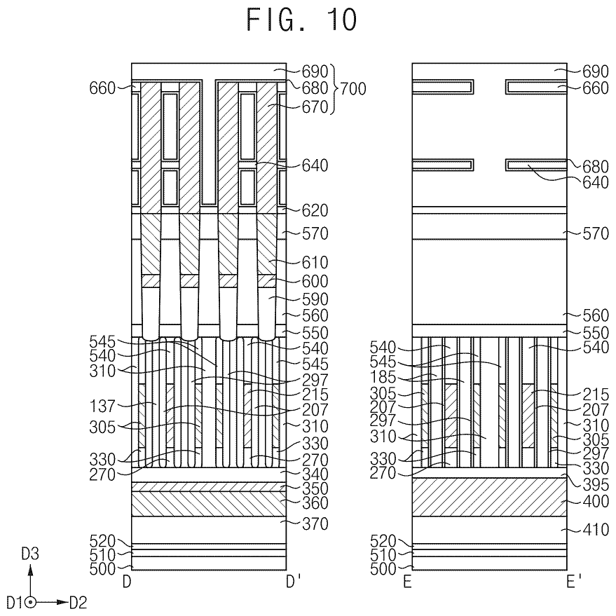

FIGS. 7 through 10 are diagrams illustrating an example of a semiconductor memory device including a vertical channel transistor. For example, FIG. 7 is a perspective view, FIG. 8 is a plan view, and FIGS. 9 and 10 are cross-sectional views. FIG. 9 includes cross-sectional views taken along lines A-A′, B-B′ and C-C′, respectively, of FIG. 8. FIG. 10 includes cross-sectional views taken along lines D-D′ and E-E′, respectively, of FIG. 8. For simplicity, FIG. 7 does not show some elements.

Referring to FIGS. 7 through 10, the semiconductor device includes a bitline structure, a first shield pattern 400, a semiconductor pattern 137, first and second gate electrodes 215 and 305, first and second gate insulation patterns 207 and 297, a contact plug structure and a capacitor 700 disposed on a second substrate 500.

The semiconductor device may further include first and second adhesion layers 520 and 510, a third spacer 395, a first insulating interlayer pattern 185, second and third insulating interlayers 310 and 560, a third insulation layer 270, fourth to seventh insulation patterns 330, 410, 540 and 545, first and second etch stop layers 550 and 620, a capping layer 570, and first and second support layers 640 and 660.

The second substrate 500 may include, e.g., a semiconductor material, an insulation material or a conductive material.

The second adhesion layer 510 and the first adhesion layer 520 may be stacked in the third direction D3, and may include an insulating material, e.g., silicon carbonitride.

The bitline structure may include a second conductive pattern 360, a barrier pattern 350 and a first conductive pattern 340 sequentially stacked in the third direction D3.

In an example, the first conductive pattern 340 may include polysilicon doped with n-type or p-type impurities, the barrier pattern 350 may include a metal nitride, e.g., titanium nitride, tantalum nitride, tungsten nitride, etc., and the second conductive pattern 360 may include a metal, e.g., tungsten, titanium, tantalum, etc.

In some implementations, a plurality of bitline structures may be spaced apart from each other in the first direction D1, and each of the plurality of bitline structures may extend in the second direction D2 on and contacting an upper surface of the first adhesion layer 520.

The first shield pattern 400 may extend in the second direction D2 between neighboring ones of the bitline structures in the first direction D1. In some implementations, an upper surface and a sidewall of the first shield pattern 400 may be covered by the third spacer 395 extending in the second direction D2, and a lower surface of the first shield pattern 400 may be covered by a fifth insulation pattern 410 extending in the second direction D2. As the first shield pattern 400 is formed, the disturbance and parasitic capacitance between the bitline structures may decrease, and thus, the RC-delay may be reduced, which may increase the operation speed of the semiconductor device.

A sidewall of the fifth insulation pattern 410 may be covered by the third spacer 395. Lower surfaces of the third spacer 395 and the fifth insulation pattern 410 may contact an upper surface of the first adhesion layer 520.

In some implementations, the third spacer 395 may contact a sidewall of the bitline structure. Upper and lower surfaces of the third spacer 395 may be substantially coplanar with upper and lower surfaces, respectively, of the bitline structure.

The first shield pattern 400 may include a metal nitride, e.g., titanium nitride, tantalum nitride, etc., and the third spacer 395 and the fifth insulation pattern 410 may include an oxide, e.g., silicon oxide.

In some implementations, a plurality of semiconductor patterns 137 may be spaced apart from each other in the second direction D2 on each of the bitline structures, and each of the plurality of semiconductor patterns 137 may contact the first conductive pattern 340 included in each of the bitline structures. As the bitline structures are spaced apart from each other in the first direction D1, a plurality of semiconductor patterns 137 may be spaced apart from each other in the first and second directions D1 and D2.

In an example, the semiconductor pattern 137 may include a single crystalline semiconductor material, e.g., single crystalline silicon, single crystalline germanium, etc., or a polycrystalline semiconductor material, e.g., polysilicon, polygermanium, etc., and may serve as a channel of the semiconductor device. However, n-type or p-type impurities may be doped into upper and lower portions of the semiconductor pattern 137, and may serve as source/drain regions of the semiconductor device, unlike a central portion of the semiconductor pattern 137 serving as the channel. Thus, current may flow in the vertical direction, that is, in the third direction D3 in the semiconductor pattern 137, and thus the semiconductor device may include a vertical channel transistor (VCT) having a vertical channel.

Alternatively, the semiconductor pattern 137 may include a single crystalline semiconductor material or a polycrystalline semiconductor material doped with n-type or p-type impurities. In this case, a concentration of the impurities in a central portion of the semiconductor pattern 137 serving as a channel may be lower than concentrations of the impurities in upper and lower portions of the semiconductor pattern 137 serving as source/drain regions, respectively.

In an example, p-type impurities may be doped into the central portion of the semiconductor pattern 137 with a relatively low concentration, and n-type impurities may be doped into the upper and lower portions of the semiconductor pattern 137 with relatively high concentrations, respectively.

The first insulating interlayer pattern 185 may be formed between neighboring ones of the semiconductor patterns 137 in the first direction D1. Thus, the semiconductor pattern 137 and the first insulating interlayer pattern 185 may be alternately and repeatedly disposed in the first direction D1.

A lower surface of the first insulating interlayer pattern 185 may contact an upper surface of the third spacer 395. In some implementations, a width in the second direction D2 of the first insulating interlayer pattern 185 may be greater than a width in the second direction D2 of the semiconductor pattern 137. The first insulating interlayer pattern 185 may include an oxide, e.g., silicon oxide.

In some implementations, a seam 181 or a void may be formed in a central portion in the first direction D1 of the first insulating interlayer pattern 185.

The second gate electrode 305 may extend in the first direction D1 at sides in the second direction D2 of the semiconductor patterns 137 and the first insulating interlayer patterns 185, and the first gate electrode 215 may extend in the first direction D1 at other sides in the second direction D2 of the semiconductor patterns 137 and the first insulating interlayer patterns 185.

For example, each of the semiconductor patterns 137 may include first and second sidewalls disposed opposite to each other in the second direction D2, each of the first insulating interlayer patterns 185 may include third and fourth sidewalls disposed opposite to each other in the second direction D2, the second gate electrode 305 may be disposed adjacent to the first sidewalls of the semiconductor patterns 137 and the third sidewalls of the first insulating interlayer patterns 185, and the first gate electrode 215 may be disposed adjacent to the second sidewalls of the semiconductor patterns 137 and the fourth sidewalls of the first insulating interlayer patterns 185.

The first and second gate electrodes 215 and 305 may include a metal, e.g., molybdenum, ruthenium, tungsten, etc., a metal nitride, e.g., titanium nitride, tantalum nitride, tungsten nitride, etc., or a metal silicide.

In some implementations, the second gate electrode 305 may be a front gate electrode with respect to each of the semiconductor patterns 137 and may serve as a wordline in the semiconductor device. The first gate electrode 215 may be a back gate electrode with respect to each of the semiconductor patterns 137.

In some implementations, the semiconductor patterns 137 may include first semiconductor patterns disposed in the first direction D1, and second semiconductor patterns disposed in the first direction D1 and spaced apart from the first semiconductor patterns in the second direction D2.

In some implementations, the wordlines may include a first wordline extending in the first direction D1 adjacent to the first sidewalls of the first semiconductor patterns and a second wordline extending in the first direction D1 adjacent to the first sidewalls of the second semiconductor patterns, and the second sidewalls of the first and second semiconductor patterns may face each other in the second direction D2. The back gate electrode 215 may be formed between the second sidewalls of the first semiconductor patterns and the second sidewalls of the second semiconductor patterns.

For example, the first wordline, the first sidewall and the second sidewall of each of the first semiconductor patterns, the back gate electrode 215, the second and first sidewalls of each of the second semiconductor patterns, and the second wordline may be disposed in the second direction D2 in this order.

In some implementations, the first and second wordlines at opposite sides, respectively, in the second direction D2 of the back gate electrode 215 may form a wordline pair, and a plurality of wordline pairs may be disposed in the second direction D2. The second insulating interlayer 310 may be formed between neighboring ones of the wordline pairs in the second direction D2, and may include an oxide, e.g., silicon oxide.

In some implementations, a width in the second direction D2 of a portion of the first gate electrode 215 adjacent to each of the first insulating interlayer patterns 185 may be greater than a width in the second direction D2 of a portion of the first gate electrode 215 adjacent to each of the semiconductor patterns 137. Thus, a width of the first gate electrode 215 in the second direction D2 may periodically vary in the first direction D1.

In some implementations, a width of the second gate electrode 305 in the second direction D2 may be constant in the first direction D1. The second gate electrode 305 may extend in the first direction D1, and a concave portion and a convex portion in the second direction D2 may be alternately and repeatedly disposed in the first direction D1.

In some implementations, upper and lower surfaces of the first gate electrode 215 may be substantially coplanar with upper and lower surfaces, respectively, of the second gate electrode 305. However, examples of the present disclosure are not limited thereto.

In some implementations, a lower surface of the first gate electrode 215 may be covered by the third insulation layer 270, and an upper surface of the first gate electrode 215 may be covered by the sixth insulation pattern 540. Additionally, a lower surface of the second gate electrode 305 may be covered by the fourth insulation pattern 330, and an upper surface of the second gate electrode 305 may be covered by the seventh insulation pattern 545.

In some implementations, lower surfaces of the third insulation layer 270 and the fourth insulation pattern 330 may be substantially coplanar with each other and may contact upper surfaces of the bitline structure and the third spacer 395. Additionally, upper surfaces of the sixth insulation pattern 540 and the seventh insulation pattern 545 may be substantially coplanar with each other.

The third insulation layer 270, and the fourth, sixth and seventh insulation patterns 330, 540 and 545 may include an oxide, e.g., silicon oxide.

The second gate insulation pattern 297 may extend in the first direction D1 on and contacting the first sidewalls of the semiconductor patterns 137 and the third sidewalls of the first insulating interlayer patterns 185, and the first gate insulation pattern 207 may extend in the first direction D1 on and contacting the second sidewalls of the semiconductor patterns 137 and the fourth sidewalls of the first insulating interlayer patterns 185. Thus, the second gate insulation pattern 297 may be formed of each of the semiconductor patterns 137 and the second gate electrode 305, and the first gate insulation pattern 207 may be formed of each of the semiconductor patterns 137 and the first gate electrode 215.

The first gate insulation pattern 207 may cover not only the sidewall of the first gate electrode 215, but also sidewalls of the sixth insulation pattern 540 and the third insulation layer 270 on and beneath, respectively, the first gate electrode 215. The second gate insulation pattern 297 may cover not only the sidewall of the second gate electrode 305, but also sidewalls of the seventh insulation pattern 545 and the fourth insulation pattern 330 on and beneath, respectively, the second gate electrode 305.

Each of the first and second gate insulation patterns 207 and 297 may include an oxide, e.g., silicon oxide. Alternatively, each of the first and second gate insulation patterns 207 and 297 may have a multi-layered structure including a first layer containing silicon oxide and contacting the semiconductor pattern 137 and a second layer containing a metal oxide, e.g., hafnium oxide, zirconium oxide, etc., and contacting a sidewall of the first layer and a sidewall of the first insulating interlayer pattern 185.

In some implementations, a width in the second direction D2 of a portion of each of the first and second gate insulation patterns 207 and 297 adjacent to the sidewall of each of the semiconductor patterns 137 may be greater than a width in the second direction D2 of a portion of each of the first and second gate insulation patterns 207 and 297 adjacent to the sidewall of each of the second insulating interlayer patterns 185. Thus, a width in the second direction D2 of each of the first and second gate insulation patterns 207 and 297 may be periodically changed in the first direction D1.

As illustrated above, if each of the first and second gate insulation patterns 207 and 297 has the multi-layered structure including the first and second layers, the portion of each of the first and second gate insulation patterns 207 and 297 contacting each of the semiconductor patterns 137 may include both of the first and second layers, while the portion of each of the first and second gate insulation patterns 207 and 297 contacting each of the second insulating interlayer patterns 185 may include only the second layer.

The first etch stop layer 550, the third insulating interlayer 560 and the capping layer 570 may be sequentially stacked on the semiconductor pattern 137, the first insulating interlayer pattern 185, the second insulating interlayer 310, the first and second gate insulation patterns 207 and 297, and the sixth and seventh insulation patterns 540 and 545, and the contact plug structure may extend through the first etch stop layer 550, the third insulating interlayer 560 and the capping layer 570 to contact an upper surface of the semiconductor pattern 137.

The first etch stop layer 550 and the capping layer 570 may include an insulating nitride, e.g., silicon nitride, and the third insulating interlayer 560 may include an oxide, e.g., silicon oxide.

As a plurality of semiconductor patterns 137 are spaced apart from each other in the first and second directions D1 and D2, a plurality of contact plug structures may also be spaced apart from each other in the first and second directions D1 and D2. In an example, the contact plug structures may be arranged in a lattice pattern in a plan view. Alternatively, the contact plug structures may be arranged in a honeycomb pattern in a plan view.

The contact plug structure may contact not only the upper surface of each of the semiconductor patterns 137, but also upper surfaces of the first and second gate insulation patterns 207 and 297 and the sixth and seventh insulation patterns 540 and 545 adjacent to each of the semiconductor patterns 137.

The contact plug structure may include a lower contact plug 590, an ohmic contact pattern 600 and an upper contact plug 610 sequentially stacked in the third direction D3.

The lower contact plug 590 may include polysilicon doped with n-type or p-type impurities, the ohmic contact pattern 600 may include a metal silicide, e.g., cobalt silicide, nickel silicide, titanium silicide, etc., and the upper contact plug 610 may include a conductive material, e.g., a metal, a metal nitride, a metal silicide, etc.

The second etch stop layer 620 may be formed on the third insulating interlayer 560 and the contact plug structure, and a first capacitor electrode 670 may extend through the second etch stop layer 620 in the third direction D3.

As the plurality of contact plug structures are spaced apart from each other in the first and second directions D1 and D2, a plurality of first capacitor electrodes 670 may also be spaced apart from each other in the first and second directions D1 and D2.

In some implementations, the first capacitor electrode 670 may have a shape of, for example, a circle, an ellipse, a polygon, a polygon with rounded corners, etc., in a plan view. In an example, the first capacitor electrodes 670 may be arranged in a lattice pattern in a plan view. Alternatively, the first capacitor electrodes 670 may be arranged in a honeycomb pattern in a plan view.

The first and second support layers 640 and 660 may contact central and upper portions, respectively, of each of the first capacitor electrodes 670 which may prevent the first capacitor electrodes 670 from falling down.

A dielectric layer 680 may be formed on surfaces of the first capacitor electrodes 670 and the first and second support layers 640 and 660, and a second capacitor electrode 690 may be formed on the dielectric layer 680. The first and second capacitor electrodes 670 and 690 and the dielectric layer 680 may collectively form the capacitor 700.

The second etch stop layer 620 may include an insulating nitride, e.g., silicon boronitride, silicon carbonitride, etc., and the first and second support layers 640 and 660 may include an insulating nitride, e.g., silicon nitride. The first capacitor electrode 670 may include a metal nitride, e.g., titanium nitride, tantalum nitride, etc., or a metal, e.g., titanium, tantalum, tungsten. The dielectric layer 680 may include a metal oxide having a high dielectric constant, e.g., hafnium oxide, zirconium oxide, etc., and the second capacitor electrode 690 may include, e.g., silicon-germanium doped with impurities.

In some examples, another type of data storage structure instead of the capacitor 700 may be formed on each of the contact plug structures, and the data storage structure may include a variable resistance pattern containing, e.g., a phase-change material, a transition metal oxide, a magnetic material, etc.

FIGS. 7 through 10 show only a cell region of the semiconductor device. However, some elements shown in FIGS. 7 through 10 may also be formed on a peripheral circuit region of the semiconductor device.

For example, FIG. 8 shows the second gate electrode 305 serving as a wordline extends in the first direction D1. However, each of the first and second wordlines forming a wordline pair may include an extension portion extending in the second direction D2 on the peripheral circuit region, and the first and second wordlines may have a ring shape on the cell region and the peripheral circuit region in a plan view. In some examples, a division layer may be formed between the first and second wordlines on the peripheral circuit region or on the cell region so that the first and second wordlines may be electrically insulated from each other.

Additionally, the first shield pattern 400 extending in the second direction D2 between neighboring bitline structures may include an extension portion extending in the first direction D1 on the peripheral circuit region, and the first shield patterns 400 spaced apart from each other in the first direction D1 on the cell region may be connected with each other on the peripheral circuit region. Contact plugs and wirings may be further formed on the peripheral circuit region to be connected to the bitline structure and the first shield pattern 400.

In some implementations, the semiconductor device may include a vertical channel transistor (VCT), which may include the semiconductor pattern 137 serving as a channel, the second gate electrode 305 serving as a front gate electrode, and the first gate electrode 215 serving as a back gate electrode. The back gate electrode 215 may increase a threshold voltage of the VCT. As a result, leakage current characteristics may not be deteriorated even if the VCT has a minute size.

Additionally, the back gate electrode 215 may be disposed between two second gate electrodes 305 to commonly apply a voltage to channels in the semiconductor patterns 137 at opposite sides, respectively. As a result, the integration degree of the semiconductor device may increase when compared to a VCT having a double gate structure in which two gate electrodes are disposed at opposite sides, respectively, of a channel.

In some implementations, the semiconductor pattern 137 of the VCT includes a single crystalline semiconductor material. As a result, the leakage current characteristics may be further enhanced.

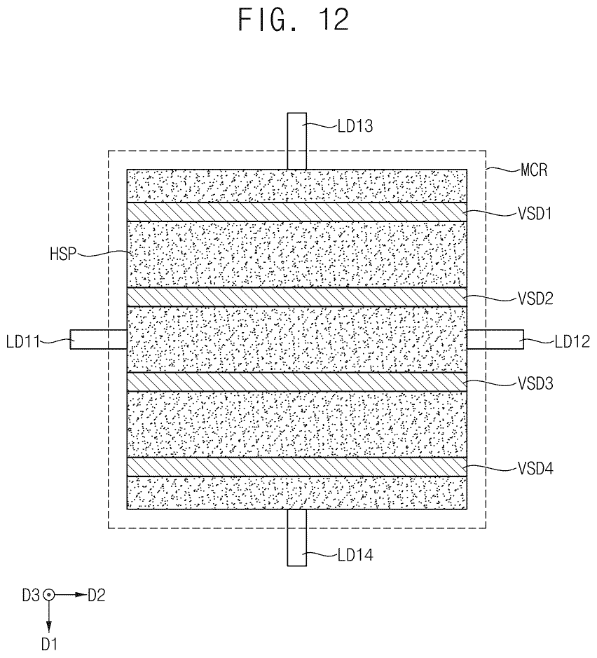

FIGS. 11 and 12 are diagrams illustrating an example of a bitline shielding structure included in a semiconductor memory device.

Referring to FIGS. 11 and 12, a bitline shielding structure BSST1 includes a plurality of vertical shielding patterns VSD1 through VSD4 and a horizontal shielding plate HSP. The plurality of vertical shielding patterns VSD1 through VSD4 may correspond to the shield patterns 400 of FIGS. 7 through 10.

The plurality of vertical shielding patterns VSD1 through VSD4 may be arranged in the first direction D1 and extend in the second direction D2 to be disposed one between the plurality of bitlines as described with reference to FIGS. 7 through 10.

The horizontal shielding plate HSP may be connected to the lower surface of the plurality of vertical shielding patterns VSD1 through VSD4 to occlude the lower spaces between the plurality of vertical shielding patterns VSD1 through VSD4.

As shown in FIG. 12, one or more voltage-applied conductive lines LD11 through LD14 may be connected to the ends in the first direction D1 or the second direction D2 of the horizontal shielding plate HSP and extend in the first direction D1 or the second direction D2 to connect with the capacitance-connection conductive path.

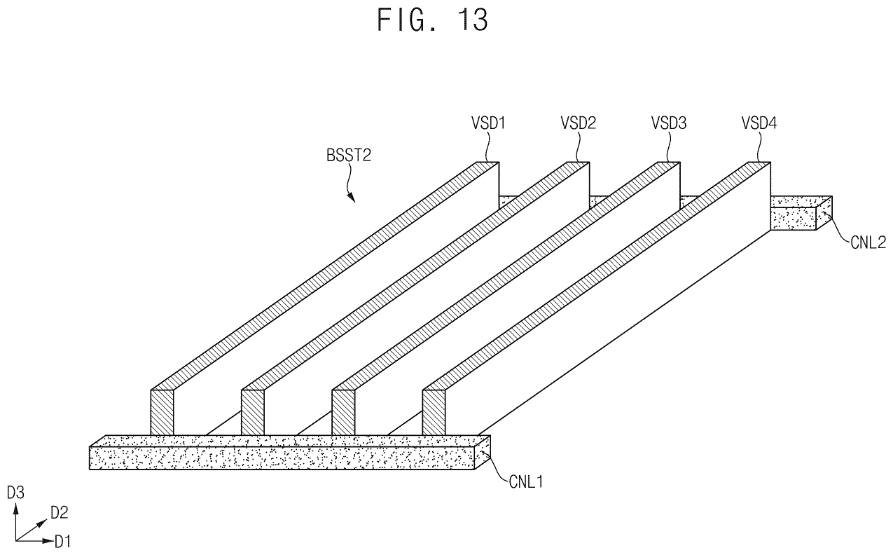

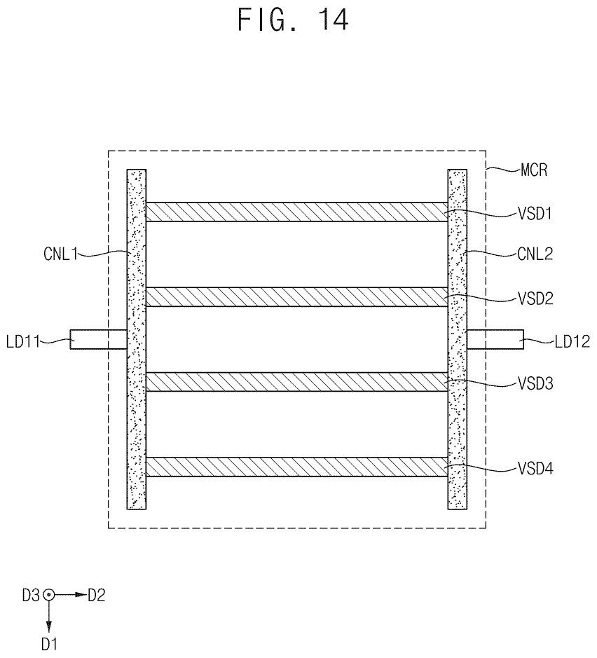

FIGS. 13 and 14 are diagrams illustrating another example of a bitline shielding structure included in a semiconductor memory device.

Referring to FIGS. 13 and 14, a bitline shielding structure BSST2 may include a plurality of vertical shielding patterns VSD1 through VSD4 arranged in the first direction D1 and extending in the second direction D2. The bitline shielding structure BSST2 may also include one or two horizontal conductive lines CNL1 and CNL2 connected to the ends in the second direction D2 of the plurality of vertical shielding patterns VSD1 through VSD4 and extending in the first direction D1.

As shown in FIG. 14, one or two voltage-applied conductive lines LD11 and LD12 may be connected to the horizontal conductive lines CNL1 and CNL2 and extend in the second direction D2 to connect with the capacitance-connection conductive path.

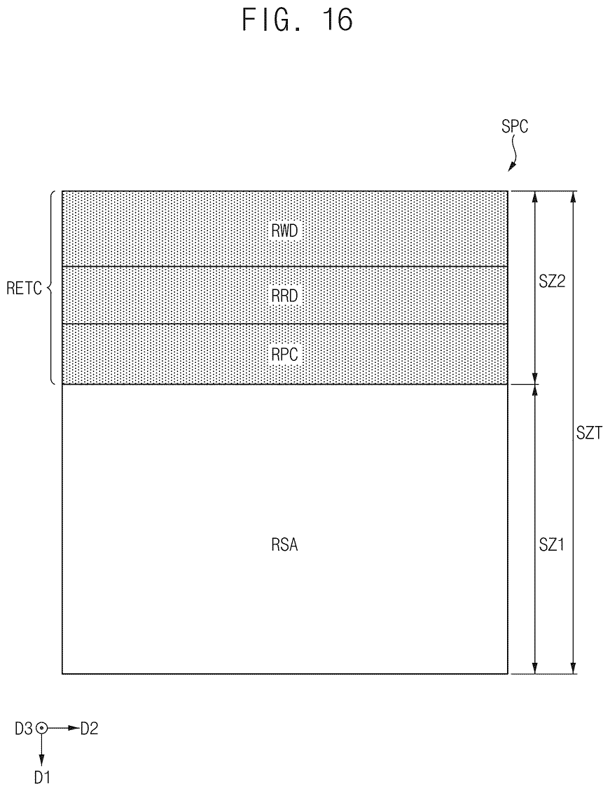

FIG. 15 is a perspective view of an example of a memory core circuit included in a semiconductor memory device, and FIG. 16 is a diagram illustrating an example layout of a sub peripheral circuit included in the memory core circuit of FIG. 15.

Referring to FIG. 15, a memory core circuit MCC includes a memory cell array MCA and a core control circuit CCC. The memory core circuit MCC may have a cell on periphery (CoP) structure where the core control circuit CCC is disposed below the memory cell array MCA.

The memory cell array MCA may include a plurality of sub cell arrays SCA arranged in a matrix of a plurality of array rows AR1 through AR4 and a plurality of array columns AC1 through AC8.

The core control circuit CCC may include a plurality of sub peripheral circuits SPC respectively arranged below the plurality of sub cell arrays SCA. The plurality of sub peripheral circuits SPC may control operations of the plurality of sub cell arrays SCA, respectively.

Each sub cell array SCA includes a plurality of memory cells, each connected to a plurality of wordlines extending in the first direction D1 and arranged in the second direction D2 and a plurality of bitlines extending in the second direction D2 and arranged in the first direction D1. Each memory cell may include a vertical channel transistor (VCT) and a cell capacitor disposed above the vertical channel transistor.

Each sub peripheral circuit SPC may include a sense amplifier region including a plurality of bitline sense amplifiers each sensing a voltage of the plurality of bitlines, as will be described below, and other regions including remaining circuitry other than the plurality of bitline sense amplifiers.

FIG. 15 illustrates thirty two sub cell arrays SCA and thirty two corresponding sub-peripheral circuits SPC arranged in four array rows AR1 through AR4 and eight array columns AC1 through AC8 for convenience of illustration and description, but examples are not limited to a particular number of array rows and array columns.

FIG. 16 illustrates a layout for one sub peripheral circuit SPC. Each of the plurality of sub peripheral circuits SPC included in the core control circuit CCC of FIG. 15 may have the configuration shown in FIG. 16.

Referring to FIG. 16, the sub peripheral circuits SPC may include a sense amplifier region RSA and a miscellaneous region RETC. The sense amplifier region RSA may include a plurality of bitline sense amplifiers each sensing a voltage of the plurality of bitlines. The miscellaneous region RETC may include circuitry other than the plurality of bitline sense amplifiers.

As shown in FIG. 16, the miscellaneous region RETC may include a wordline driver region RWD including a plurality of sub wordline drivers driving each of the plurality of wordlines, a decoder region RRD including row decoding circuitry controlling the plurality of sub wordline drivers to select at least one of the plurality of wordlines, and a power and control region RPC including power circuitry supplying power to each of the sub peripheral circuits SPC and control circuitry controlling operation of each of the sub peripheral circuits SPC.

The wordline driver region RWD, the sense amplifier region RSA, the decoder region RRD, and the power and control region RPC may be disposed in the first direction D1.

In some implementations, as shown in FIG. 16, the wordline driver region RWD and the sense amplifier region RSA may be disposed at both end portions of the first direction D1 of each sub peripheral circuit SPC.

The decoder region RRD may be disposed adjacent to the wordline driver region RWD in the first direction D1 between the wordline driver region RWD and the sense amplifier region RSA.

The power and control region RPC may be disposed adjacent to the sense amplifier region RSA in the first direction D1 between the wordline driver region RWD and the sense amplifier region RSA.

As shown in FIG. 16, the length SZT in the first direction D1 of each sub peripheral circuit SPC corresponds to the sum of the length SZ1 in the first direction D1 of the sense amplifier region RSA and the length SZ2 in the first direction D1 of the miscellaneous region RETC. In some implementations, the length SZ1 in the first direction D1 of the sense amplifier region RSA may be more than half the length SZT in the first direction D1 of each sub peripheral circuit SPC for efficient placement of the bitline sense amplifiers. In other words, the length SZ1 in the first direction D1 of the sense amplifier region RSA may be greater than or equal to the length SZ2 in the first direction D1 of the miscellaneous region RETC.

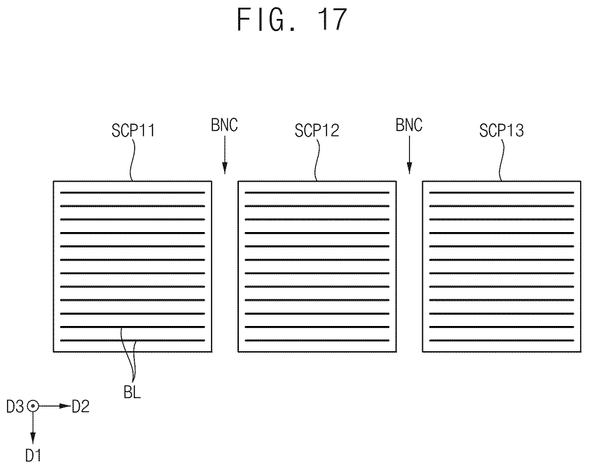

FIG. 17 is a diagram illustrating an example of an arrangement of bitlines included in the memory core circuit of FIG. 15.

FIG. 17 illustrates a first sub peripheral circuit SPC11, a second sub peripheral circuit SPC12, and a third sub peripheral circuit SPC13 disposed adjacent and sequentially in the second direction D2 in one array column (e.g., first array column AC1 of FIG. 15).

Referring to FIG. 17, a plurality of bitlines BL are arranged above each of the sub peripheral circuits of the first sub peripheral circuit SPC11, the second sub peripheral circuit SPC12, and the third sub peripheral circuit SPC13.

As shown in FIG. 17, the bitlines BL may be cut, e.g., discontinuous, at the boundary regions BNC between the sub peripheral circuits SPC11, SPC21 and SPC31. Through such cuts, an open bitline structure may be implemented.

FIG. 18 is a diagram illustrating examples of a capacitance-connection conductive path included in a semiconductor memory device.

FIG. 18 illustrates a CoP structure in which the cell capacitors CP are disposed on top in the third direction D3 and the bitlines BL are disposed on the bottom in the third direction D3. As described with reference to FIGS. 7 through 10, wordlines may be disposed between the cell capacitors CP and the bitlines BL. The bitlines BLa and BLb may be connected to a bitline sense amplifier BLSA included in the sense amplifier region RSA via conductive patterns PT, vertical contacts VC formed on the conductive layers BP and LM.

In the example as shown in FIG. 18, the bitline BLb of the sub peripheral circuit SPC12 may be connected to the bitline sense amplifier BLSA included in the sense amplifier region RSA of the neighboring sub peripheral circuit SPC11 via a horizontal conductive path CCP formed in the boundary region BNC of the second direction D2 between the neighboring sub peripheral circuits SPC11 in the second direction D2. The horizontal conduct path CCP may be connected to the bitline BLb via a vertical path VPH.

As such, the horizontal conductive path CCP may extend in the second direction D2 across the boundary region BNC to connect the bitline BLb and the bitline sense amplifier BLSA.

As shown in FIG. 18, each bitline sense amplifier BLSA may be coupled to one bitline BLb and the complementary bitline BLa together. For example, the one bitline BLb may correspond to a bitline of the sub peripheral circuit SPC12 and the complementary bitline BLa may correspond to a bitline of the neighboring sub peripheral circuit SPC11.

As such, the memory core circuit may have an open bitline structure in which each bitline sense amplifier BLSA is connected to one bitline BLb disposed on the upper side of each sub peripheral circuit SPC21 and one complementary bitline BLa disposed on the upper side of the neighboring sub peripheral circuit SPC11. In this case, the one bitline BLb and the complementary bitline BLa that are connected to the respective bitline sense amplifiers BLSA may be disposed at the same location in the first direction D1.

As shown in FIGS. 17 and 18, the plurality of bitlines are cut at the boundary regions BNCs of the sub peripheral circuits SCP11, SPC12 and SPC13 arranged in the second direction D2.

Referring to FIG. 18, the aforementioned bitline shielding structure BSST may include sub bitline shielding structures BSST11 and BSST12 corresponding to the sub peripheral circuits SCP11 and SPC12, respectively, and a first horizontal conductive line CCP1 formed in the boundary region BNC to connect the sub bitline shielding structures BSST11 and BSST12. Further, the aforementioned plate electrode structure PEST may include sub plate electrode structures PEST11 and PEST12 corresponding to the sub peripheral circuits SCP11 and SPC12, respectively, and a second horizontal conductive line CCP2 formed in the boundary region BNC connecting the sub plate electrode structures PEST11 and PEST12.

The core connection conductive path CPH described with reference to FIG. 1 may be formed in the boundary regions BNC. As shown in FIG. 18, the core connection conductive path CPH may include a vertical contact VC1 extending from the boundary region BNC in the third direction D3. The vertical contact VC1 may connect the first horizontal conductive line CCP1 formed in the boundary region BNC and corresponding to a portion of the bitline shielding structure BSST and the second horizontal conductive line CCP2 formed in the boundary region BNC and corresponding to a portion of the plate electrode structure PEST. In this way, the bitline shielding structure BSST and the plate electrode structure PEST may be efficiently connected by arranging the core connection conductive path CPH in the boundary regions BNC.

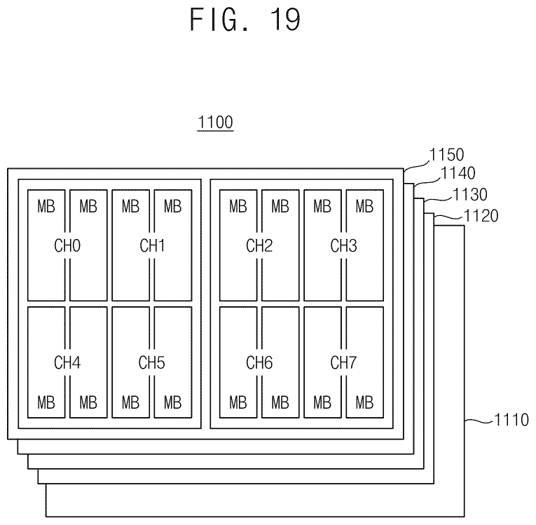

FIG. 19 is a diagram illustrating an example of a stacked memory device.

FIG. 19 illustrates an example of the structure of a high-bandwidth memory. Referring to FIG. 19, a high bandwidth memory (HBM) 1100 may include a structure in which a plurality of DRAM semiconductor dies 1120, 1130, 1140 and 1150 are stacked. The plurality of DRAM semiconductor dies 1120, 1130, 1140 and 1150 correspond to the core semiconductor dies described above.

The high bandwidth memory may be optimized for high bandwidth operation of the stacked structure through a plurality of independent interfaces called channels. According to the HBM standard, each DRAM stack may support a variety of channels.

Although FIG. 19 illustrates an example in which four DRAM semiconductor dies are stacked, examples are not limited thereto. Each semiconductor die may provide additional capacity and additional channels to the stacked structure. Each channel provides access to an independent set of DRAM banks. A request from one channel does not access data attached to another channel. The channels are independently clocked and do not need to be synchronized with each other. FIG. 19 illustrates an example in which the memory banks MB of each DRAM semiconductor die are grouped into eight independent channels CH0-CH7, but examples are not limited thereto.

The high bandwidth memory 1100 may include a buffer die or interface die 1110 located at the bottom of the stack structure and providing signal redistribution and other functions. Functions typically implemented in the DRAM semiconductor dies 1120, 1130, 1140 and 1150 may be implemented in this interface die 1110.

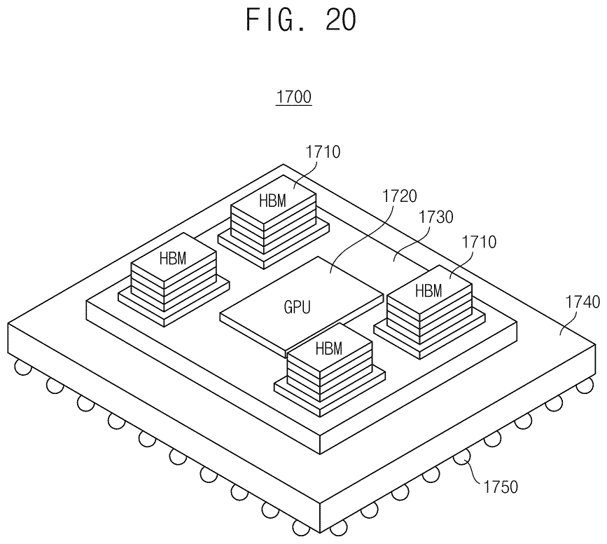

FIG. 20 is a diagram illustrating an example structure of a semiconductor package including a semiconductor memory device.

Referring to FIG. 20, a semiconductor package 1700 includes one or more stacked memory devices 1710 and a graphics processing unit (GPU) 1720. The stacked memory devices 1710 and the GPU 1720 may be mounted on an interposer 1730, and the interposer 1730 on which the stacked memory devices 1710 and the GPU 1720 are mounted may be mounted on a package substrate 1740. The GPU 1720 may perform substantially the same function as the aforementioned memory controller or may include a memory controller therein. The GPU 1720 may store data generated or used in graphic processing in one or more stacked memory devices 1710.

The stacked memory device 1710 may be implemented in various forms, and the stacked memory device 1710 may be a memory device in the form of a high bandwidth memory (HBM) in which a plurality of layers are stacked. Accordingly, the stacked memory device 1710 may include a buffer semiconductor die and a plurality of core semiconductor dies.

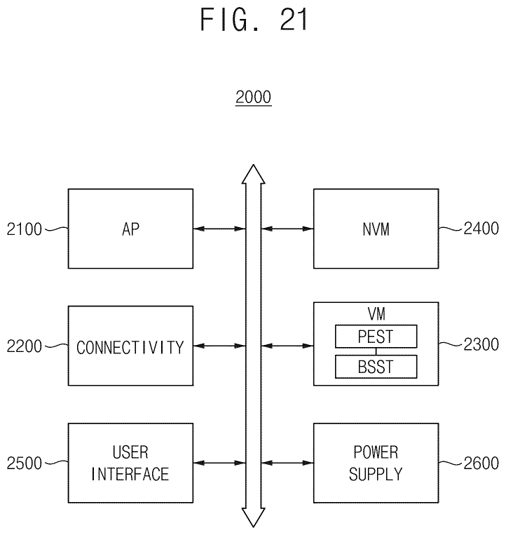

FIG. 21 is a block diagram illustrating an example of a mobile system including a semiconductor memory device.

Referring to FIG. 21, a mobile system 2000 includes an application processor 2100, a connectivity unit 2200, a semiconductor memory device 2300, a nonvolatile semiconductor memory device 2400, a user interface 2500 and a power supply 2600. In some implementations, the mobile system 2000 may be any mobile system, such as a mobile phone, a smart phone, a personal digital assistant (PDA), a portable multimedia player (PMP), a digital camera, a music player, a portable game console, a navigation system, etc. The application processor 2100 may execute applications that provide an Internet browser, a game, a video, etc. The connectivity unit 2200 may perform wireless or wired communication with an external device. The semiconductor memory device 2300 may store data processed by the application processor 2100 or may operate as a working memory.

The nonvolatile semiconductor memory device 2400 may store user data and a boot image for booting the mobile system 2000. The user interface 2500 may include one or more input devices such as a keypad, a touch screen, and/or one or more output devices such as a speaker, a display device. The power supply 2600 may supply an operation voltage of the mobile system 1200.

In some implementations, the semiconductor memory device 2300 may include a plate electrode structure PEST, a bitline shielding structure BSST, and a capacitance-connection conductive path PH connecting the plate electrode structure PEST and the bitline shielding structure BSST.

Aspects of the present disclosure may be applied to any electronic devices and systems. For example, the inventive concept may be applied to systems such as a memory card, a solid state drive (SSD), an embedded multimedia card (eMMC), a universal flash storage (UFS), a mobile phone, a smart phone, a personal digital assistant (PDA), a portable multimedia player (PMP), a digital camera, a camcorder, a personal computer (PC), a server computer, a workstation, a laptop computer, a digital TV, a set-top box, a portable game console, a navigation system, a wearable device, an internet of things (IoT) device, an internet of everything (IoE) device, an e-book, a virtual reality (VR) device, an augmented reality (AR) device, a server system, an automotive driving system, etc.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The foregoing is illustrative of examples and is not to be construed as limiting thereof. Although a few examples have been described, those skilled in the art will readily appreciate that many modifications are possible in the examples without materially departing from the present inventive concept.

What is claimed is:

1. A semiconductor memory device comprising:
a plurality of bitlines arranged in a first direction parallel to a surface of a semiconductor substrate and extending in a second direction parallel to the surface of the semiconductor substrate and perpendicular to the first direction;
a memory cell array including a plurality of memory cells connected to the plurality of bitlines, wherein the plurality of memory cells are arranged in the first direction and the second direction, and each memory cell includes a cell transistor and a cell capacitor that are arranged in a third direction perpendicular to the surface of the semiconductor substrate;
a plate electrode structure providing a common electrode of cell capacitors included in the plurality of memory cells;
a bitline shielding structure between the plurality of bitlines; and
a conductive path connecting the plate electrode structure and the bitline shielding structure.

2. The semiconductor memory device of claim 1, wherein the semiconductor memory device comprises a memory core region, in which the memory cell array is arranged, and comprises a peripheral circuit region disposed adjacent to the memory core region in the first direction or the second direction.

3. The semiconductor memory device of claim 2, wherein the conductive path includes a peripheral connection conductive path arranged in the peripheral circuit region.

4. The semiconductor memory device of claim 3, wherein the peripheral connection conductive path includes:
a first conductive line connected to the bitline shielding structure and extending in the first direction or the second direction;
a second conductive line connected to the plate electrode structure and extending in the first direction or the second direction; and
a vertical contact extending in the third direction and connecting the first conductive line and the second conductive line,
wherein the first and second conductive line are configured to be connected to a voltage source.

5. The semiconductor memory device of claim 3, wherein the peripheral connecting conductive path includes:
a first conductive line connected to the bitline shielding structure and extending in the first direction or the second direction;
a second conductive line connected to the plate electrode structure and extending in the first direction or the second direction;
a first test pad and a second test pad on a top surface of a core semiconductor die in which the memory cell array is arranged;
a first vertical contact extending in the third direction and connecting the first conductive line and the first test pad;
a second vertical contact extending in the third direction and connecting the second conductive line and the second test pad; and
a third conductive line on the top surface of the core semiconductor die and connecting the first test pad and the second pad,
wherein the first and second conductive line are configured to be connected to a voltage source.

6. The semiconductor memory device of claim 3, wherein the peripheral connection conductive pathway includes:
a first conductive line connected to the bitline shielding structure and extending in the first direction or the second direction;
a second conductive line connected to the plate electrode structure and extending in the first direction or the second direction;
a first core pad and a second core pad on a bottom surface of a core semiconductor die in which the memory cell array is arranged;
a first vertical contact extending in the third direction and connecting the first conductive line and the first core pad;
a second vertical contact extending in the third direction and connecting the second conductive line and the second core pad;
a first peripheral pad and a second peripheral pad on a top surface of a peripheral semiconductor die, which is bonded to the bottom surface of the core semiconductor die, wherein the first peripheral pad and the second peripheral pad are bonded to the first core pad and the second core pad;
a horizontal conductive line in the peripheral semiconductor die and extending in the first direction or the second direction;
a third vertical contact extending in the third direction and connecting the first peripheral pad and the horizontal conductive line; and
a fourth vertical contact extending in the third direction and connecting the second peripheral pad and the horizontal conductive line,
wherein the first and second conductive line are configured to be connected to a voltage source.

7. The semiconductor memory device of claim 3, wherein the peripheral connecting conductive path includes:
a first conductive line connected to the bitline shielding structure and extending in the first direction or the second direction;
a second conductive line connected to the plate electrode structure and extending in the first direction or the second direction;
a first core pad and a second core pad on a bottom surface of a core semiconductor die in which the memory cell array is arranged;
a first vertical contact extending in the third direction and connecting the first conductive line and the first core pad;
a second vertical contact extending in the third direction and connecting the second conductive line and the second core pad; and
a third conductive line on the bottom surface of the core semiconductor die and connecting the first core pad and the second core pad,
wherein the first and second conductive line are configured to be connected to a voltage source.

8. The semiconductor memory device of claim 2, wherein the conductive path includes a core connection conductive path in the core circuit region.

9. The semiconductor memory device of claim 1, wherein the bitline shielding structure includes:
a plurality of vertical shielding patterns arranged in the first direction and extending in the first direction, wherein each vertical shielding pattern of the plurality of vertical shielding patterns is arranged between adjacent bitlines of the plurality of bitlines; and
a horizontal shielding plate connected to bottom surfaces of the plurality of vertical shielding patterns to occlude lower spaces between the plurality of vertical shielding patterns.

10. The semiconductor memory device of claim 9, further comprising:
a conductive line connected to an end of the horizontal shielding plate and extending in the first direction or the second direction to connect with the conductive path.

11. The semiconductor memory device of claim 1, wherein the bitline shielding structure includes:
a plurality of vertical shielding patterns arranged in the first direction and extending in the second direction, wherein each vertical shielding pattern of the plurality of vertical shielding patterns is arranged between adjacent bitlines of the plurality of bitlines.

12. The semiconductor memory device of claim 11, wherein the bitline shielding structure includes:
a horizontal conductive line connected to ends of the plurality of vertical shielding patterns and extending in the first direction.

13. The semiconductor memory device of claim 12, wherein the conductive line is a first conductive line, and further comprising:
a second conductive line connected to the horizontal conductive line and extending in the second direction to connect with the conductive path.

14. The semiconductor memory device of claim 1, further comprising:
a core control circuit below the memory cell array and configured to control operation of the memory cell array.

15. The semiconductor memory device of claim 14, wherein the memory cell array includes a plurality of sub cell arrays arranged in the form of a matrix, wherein the matrix comprises a plurality of array rows and a plurality of array columns, and
wherein the core control circuit includes a plurality of sub-peripheral circuits respectively arranged below the plurality of sub cell arrays and configured to respectively control operations of the plurality of sub cell arrays.

16. The semiconductor memory device of claim 15, wherein the plurality of bitlines discontinue at boundary regions of the sub-peripheral circuits, wherein the sub-peripheral circuits are arranged in the second direction, and
wherein the conductive path includes a core connection conductive path formed in the boundary regions.

17. The semiconductor memory device of claim 14, wherein the memory cell array arranged in a core semiconductor die, the core control circuit is arranged in a peripheral semiconductor die, and the core semiconductor die and the semiconductor memory device comprise a cell over periphery (CoP) structure in which the core semiconductor die and the peripheral semiconductor die are stacked in the third direction.

18. The semiconductor memory device of claim 1, wherein the cell transistor is a vertical channel transistor in which a channel extends in the third direction, and the cell capacitor is disposed above the vertical channel transistor in the third direction.

19. A semiconductor memory device comprising:
a plurality of bitlines;
a memory cell array including a plurality of memory cells connected to the plurality of bitlines, each memory cell including a cell transistor and a cell capacitor;
a plate electrode structure configured to provide a common plate voltage to the plurality of memory cells;
a bitline shielding structure between adjacent bitlines of the plurality of bitlines; and
a conductive path connecting the plate electrode structure and the bitline shielding structure.

20. A semiconductor memory device comprising:
a plurality of bitlines arranged in a first direction parallel to a surface of a semiconductor substrate and extending in a second direction parallel to the surface of the semiconductor substrate and perpendicular to the first direction;
a memory cell array including a plurality of memory cells connected to the plurality of bitlines, the plurality of memory cells being arranged in the first direction and the second direction, each memory cell including a vertical channel transistor in which a channel extends in the third direction and a cell capacitor that is above the vertical channel transistor in the third direction;
a plate electrode structure providing a common electrode of cell capacitors included in the plurality of memory cells;
a bitline shielding structure between the plurality of bitlines; and
a conductive path connecting the plate electrode structure and the bitline shielding structure,
wherein the semiconductor memory device comprises a memory core region, in which the memory cell array is formed, and a peripheral circuit region adjacent to the memory core region in the first direction or the second direction, and
wherein the conductive path includes a peripheral connection conductive path formed in the peripheral circuit region and a core connection conductive path formed in the core circuit region.
